(19) United States
(12) Patent Application Publication
(10) Pub. No.: US 2017/0250715 A1
(43) Pub. Date: Aug. 31, 2017

(54) DEVICE COMPRISING A RADIO COMMUNICATION TERMINAL

(71) Applicant: THALES, Courbevoie (FR)

(72) Inventors: Wilfried Alain DEMENITROUX, Cholet (FR); Cedrick SABOUREAU, Cholet (FR); Pierre-Yves MAILLOUX, Cholet (FR); Bertrand GERFAULT, Cholet (FR)

(73) Assignee: THALES, Courbevoie (FR)

(21) Appl. No.: 15/506,518

(22) PCT Filed: Aug. 25, 2015
(86) PCT No.: PCT/EP2015/069466

§ 371 Date: Feb. 24, 2017

(30) Foreign Application Priority Data
Aug. 27, 2014 (FR) 14/01907

(51) Int. Cl. H04B 1/04; H03H 7/38; H03H 7/01

(52) U.S. Cl. CPC H04B 1/04; H03H 7/0153; H03H 7/38

(57) ABSTRACT

The invention relates to a radio communication terminal (10) comprising:

an antenna (12) having an impedance;

an impedance-measuring sensor (14) for measuring the impedance of the antenne (12) in order to produce a measured impedance;

an amplifier (18);

a filter (20) connected to the antenna (12) and the amplifier (18), the filter (20) having a variable impedance; and

a body (22) for controlling the impedance of the filter (20), the body being used to control the impedance of the filter (20) according to the measured impedance.

The present invention relates to a radiocommunication station and to a device including such a radiocommunication station. The present invention also relates to an associated method for matching impedance.

A radiocommunication station usually includes a power amplifier and an antenna. In multiple applications, the antennas are strongly mismatched relatively to the power amplifier, this causing sub-operating conditions. Notably, the transmitted power, the consumption and the linearity are strongly degraded. In certain cases, the output of the power amplifier breaks.

In order to find a remedy to the preceding problems, antenna matching casings have been proposed.

However, such casings cause power losses and therefore a degradation of the sensitivity of the receiving portion, and a strong yield loss in transmission. This notably generates over-consumption and a bothersome congestion for certain applications.

Therefore there exists a need for a radiocommunication station having a better yield.

For this, a radiocommunication station is proposed comprising an antenna having an impedence, a sensor for measuring impedance able to measure the impedance of the antenna in order to obtain a measured impedance, an amplifier, a filter connected to the antenna and to the amplifier, the filter having a variable impedance and a member for controlling the impedance of the filter, the member being able to control the impedance of the filter depending on the measured impedance.

According to particular embodiments, the radiocommunication station comprises one or several of the following features, taken individually or according to any technically possible combination:
the filter comprises at least one electronic component with a variable value,
   said at least one electronic component of variable value comprises a plurality of electronic components of a fixed value each connected through a respective controlled switch, the control member being able to control each switch,
   the control member is able to control the impedance of a filter (20) so that the impedance of the filter is equal to the conjugate impedance of the measured impedance to within 10% of the modulus of the measured impedance,
   the filter is an LC circuit,
   the LC circuit comprises an input and an output, an element generating an inductive impedance connecting the input to the output and a first capacitor connecting the input to the ground and a second capacitor connecting the output to the ground,
   the station includes, in addition, a power measurement sensor, the power measurement sensor measuring the power reflected by the filter in order to obtain a measured reflected power, the control member being able to control the impedance of the filter also depending on the measured reflected power,
   the control member is able to control the impedance of the filter (20) at a regular time interval.

Thus a device, notably a mobile phone, including a station as described earlier is also proposed. A method for matching impedance in a radiocommunication station is also proposed, comprising an antenna having an impedance, an impedance measurement sensor, an amplifier, a filter connected to the antenna and to the amplifier, the filter having a variable impedance, and a control member of the impedance of the filter. The matching method includes steps for measuring the impedance of the antenna with the impedance measurement sensor in order to obtain a measured impedance, and steps for controlling the impedance of the filter according to the measured impedance.

Other features and advantages of the invention will become apparent upon reading the description which follows of embodiments of the invention, given only as an example and with reference to the drawings which are:

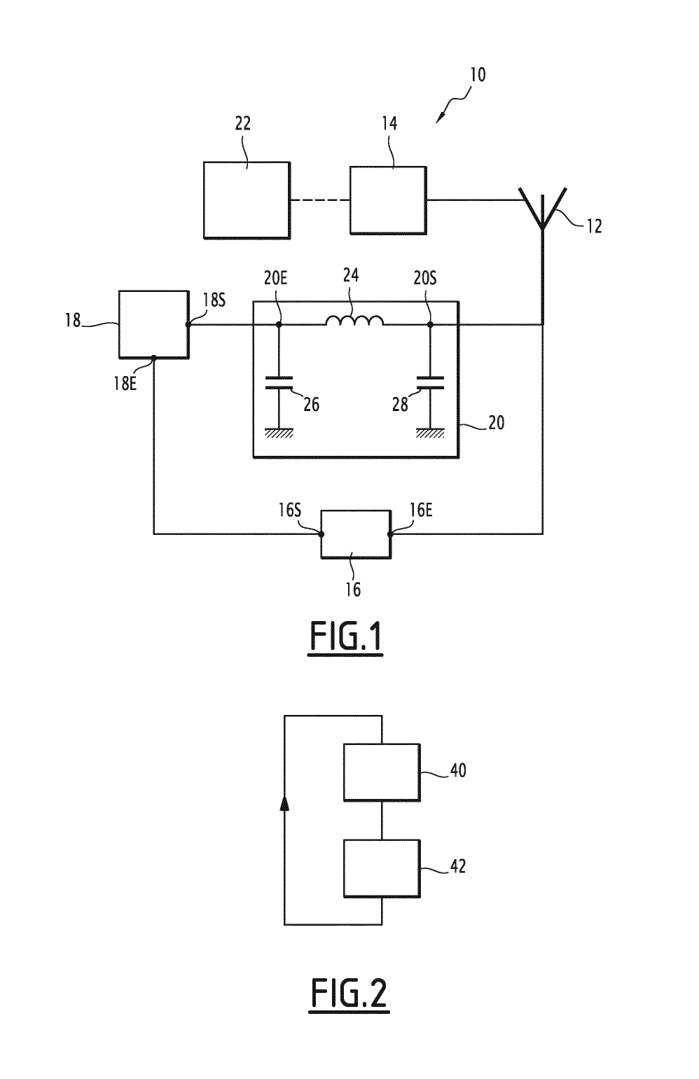

FIG. 1, a schematic illustration of an exemplary radiocommunication station,

FIG. 2, a diagram of a flowchart illustrating an exemplary embodiment of a impedance matching method, and

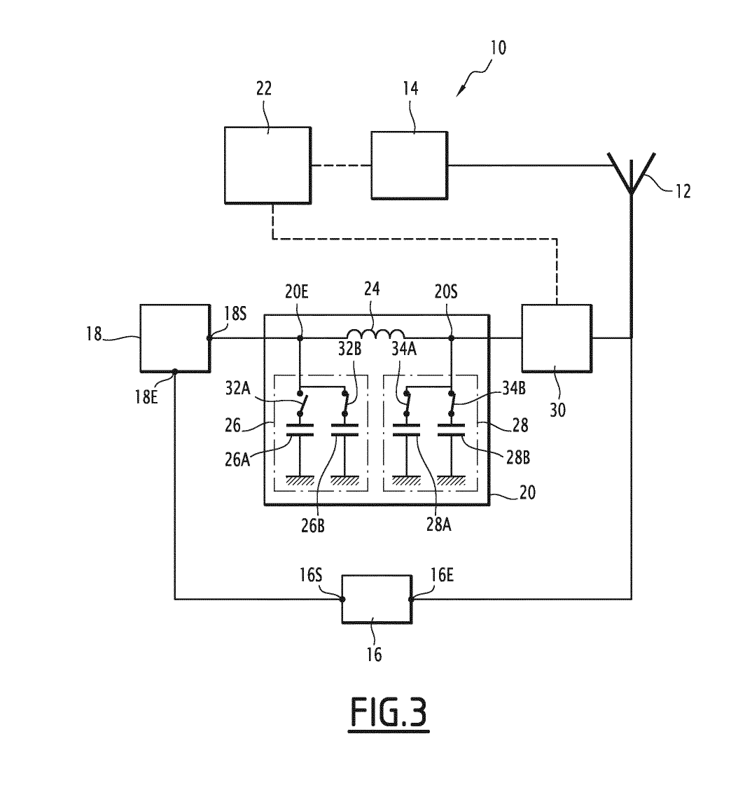

FIG. 3, a schematic illustration of another exemplary radiocommunication station.

A radiocommunication station 10 is schematically illustrated in FIG. 1.

A radiocommunication station 10 is a station capable of emitting radiocommunications, of receiving radiocommunications and of processing the signals from the transmitted or received radiocommunications.

A radiocommunication is telecommunication carried out in space by means of electromagnetic waves. These waves form propagation of energy appearing under the form of an electric field coupled with a magnetic field. The information is transported by constant modulation of the properties of the wave, i.e. its amplitude, its frequency, its phase or inter alia by the width of a pulse.

The radiocommunication station 10 includes an antenna 12, an impedance measurement sensor 14, a processing unit 16, an amplifier 18, a filter 20 and a member 22 for controlling the impedance of the filter 20.

The antenna 12 is a radio-electric antenna, and a device able to receive and/or transmit radio waves.

The antenna 12 is preferably a wide band antenna covering a few octaves (a few MHz to a few hundred MHz).

The antenna 12 has an impedance. By definition, the electric impedance measures the opposition of an electric circuit to the passage of an alternating sign-wave current. The definition of impedance is a generalization of Ohm's Law in the study of AC current circuit. The impedance of a passive linear dipole with terminals A and B is defined under current and voltage sign-wave conditions by the quotient of the image complex number of the phaser, representing the voltage between the terminals, by the image complex number of the phaser, representing the electric current through the dipole.

The impedance measurement sensor 14 is able to measure the impedance of the antenna 12.

The impedance measurement sensor 14 is thus able to deliver a signal proportional to the impedance of the antenna 12. The signal delivered by the measurement sensor is generally an electric signal.

Preferably, the impedance measurement sensor 14 is able to measure the impedance of the antenna 12 both in amplitude and in phase.

According to the example of FIG. 1, the impedance measurement sensor 14 includes a coupler measuring the modulus of the impedance of the antenna 12 and a phase detector measuring the phase of the impedance of the antenna 12.

The impedance measurement sensor 14 is connected with the control member 22 as well as as shown by the dotted lines in FIG. 1. The dotted lines indicate that the signal delivered by the impedance measurement sensor 14 is transmitted to the control member 22.

The processing unit 16 is able to process the signals from the transmitted or received radiocommunications.

In the example shown in FIG. 1, the processing unit 16 includes an input 16E and an output 16S.

In the case of transmission, the processing unit 16 is able to generate signals to be transmitted by the antenna 12, the signals being transmitted on the output 16S of the processing unit 16.

For reception, the processing unit 16 is able to extract relevant pieces of information from the radiocommunications received by the antenna 12. For this, the input 16E of the processing unit 16 is connected to the antenna 12.

The amplifier 18 has an input 18E and an output 18S. The amplifier 18 is able to amplify the amplitude of a wave at the input 18E. The amplifier 18 emits the amplified wave on the output 18S of the amplifier 18.

The amplifier 18 is often described as a power amplifier 18 because the amplifier 18 very strongly increases the amplitude of the wave at the input 18E. The amplitude of the wave obtained at the output of the amplifier 18 has a power of the order of a few hundred Watts.

More specifically, in the illustrated case, the input 18E of the amplifier 18 is connected to the output 16S of the processing unit 16. The amplifier 18 amplifies the signal transmitted by the processing unit 16.

According to the example of FIG. 1, the amplifier 18 has an impedance of 50 ohms.

The filter 20 is connected to the antenna 12. In this case, the filter 20 is connected to the antenna 12 through a wired connection.

Advantageously, the distance between the antenna 12 and the filter 20 is greater than or equal to 100 cm.

The filter 20 is also connected to the amplifier 18. In this case, the filter 20 is connected to the amplifier 18 through a wired connection.

Preferably, the distance between the amplifier 18 and the filter 20 is less than or equal to 1 cm.

The filter 20 is thereby positioned between the amplifier 18 and the antenna 12.

The filter 20 is able to ensure a function of harmonic filtering between the amplifier 18 and the filter 20. Formulated otherwise, the filter 20 is an “anti-harmonic” filter 20. As an example, if f0 is the operating frequency, the filter 20 is able to filter the harmonics for which the frequency is comprised between 2*f0 and 10*f0.

Preferably, the filter 20 is a low-pass filter 20.

The filter 20 has variable impedance.

For this, the filter 20 comprises at least one electronic component of the variable value.

Under this context, a variable value corresponds to an electric quantity. For example, the electronic component is a capacitor for which the capacitance is variable, a potentiometer or a coil 24 for which the inductance is variable.

According to the example of FIG. 1, the filter 20 is an LC circuit.

An LC circuit is an electrical circuit comprising at least one generator dipole with inductive impedance and at least one generator dipole with capacitive impedance.

As an example, the generator dipole with inductive impedance is a coil 24. A coil 24, solenoid, self-inductance or sometimes self is a common component in electrotechnics and electronics. A coil 24 consists of a winding of a conductive wire optionally around a core in a ferromagnetic material which may be an assembly of metal sheets or a ferrite block (ferromagnetic ceramic). French physicist and engineers often call this term by synecdoche “inductance”, this term designating the characteristic property of the coil 24 which is its opposition to the variation of current in its turns.

According to another example, the generator dipole with an inductive impedance is a quarter wave line, i.e. a piece of a transmission line for which the wavelength is equal to the quarter of the wavelength of the signal conveyed over the relevant quarter wave line.

In the particular case of FIG. 1, the LC circuit includes an input 20E and an output 20S, the input 20E being connected to the output 18S of the amplifier 18 and the output 20S of the LC circuit being connected to the antenna 12.

The LC circuit also includes a coil 24 with variable inductance connecting the input 20E of the LC circuit to the output 20S of the LC circuit.

The LC circuit also comprises a first capacitor 26 with variable capacitance connecting the input 20E of the circuit LC to the ground.

The LC circuit also includes a second capacitor 28 connecting the output 20S of the LC circuit to the ground.

The member 22 for controlling the impedance of the filter 20 is able to control the impedance of the filter 20 according to the impedance measured by the sensor.

In the case illustrated in FIG. 1, the control member 22 is able to control the impedance of the filter 20 so that the impedance of the filter 20 is equal to the conjugate impedance of the impedance measured by the sensor to within 10% of the modulus of the impedance of the filter 20.

In mathematics, the conjugate of a complex number is the complex number formed with the same real part but with the opposite imaginary part.

In order to control the impedance of the filter 20, the control member 22 is able to modify the values of the coil 24 and of the capacitors 26 and 28.

The operation of the radiocommunication station 10 is now described with reference to an impedance matching method applied to the radiocommunication station 10.

The impedance matching method includes a step for measuring the impedance of the antenna 12.

The step for measuring the impedance is applied by means of the impedance measurement sensor 14.

At the end of the measurement step, the control member 22 receives a signal delivered by the impedance measurement sensor.

The impedance matching method also comprises a step for controlling the impedance of the filter 20 according to the impedance measured in the measurement step.

For this, the control member 22 imposes that the impedance of the filter 20 is equal to the impedance measured to within 10% of the modulus of the impedance of the filter 20.

Because of the re-configurability of the impedance of the filter 20, the matching method is preferably repeated as desired. This is what indicates the arrow in FIG. 2.

As an example, the matching method is applied at a regular time interval.

For example, the interval between two matches is less than or equal to 1 microsecond.

Thus, when the impedance of the antenna 12 is far from 50 ohms, the filter 20 is a cell for matching the impedance of the antenna 12 with the impedance of the amplifier 18. A 20% to 30% gain in terms of power on the whole station is obtained. The matching is efficient for the stationary wave levels which may range up to 5.

The control member 22 therefore gives the possibility of controlling the impedance of the filter 20 in order to match the impedance of the antenna 12 to the impedance of the amplifier 18.

The radiocommunication station 10 thus gives the possibility of guaranteeing the performances of the antenna 12 used in a wide band. Such performances are notably expressed in terms of linearity, of yield or of power. The radiocommunication station 10 thus has a better yield.

The station also ensures protection of the amplifier 18.

The proposed station is compact since the station has reduced bulkiness. Indeed, the filter 20 is a single component fulfilling two functions which are filtering and impedance matching.

The station also has the advantage of being relatively inexpensive to make. Indeed, only electronic components available commercially are used, and this without any specific adjustment.

The radiocommunication station 10 is applied in multiple fields. Thus, a device comprising a radiocommunication station 10 as described earlier is proposed. The device is typically a piece of power electronic equipment. For example, the device is a portable telephone.

Another embodiment of the radiocommunication station 10 is illustrated in FIG. 3.

The radiocommunication station 10 includes the same elements as the radiocommunication station 10 described with reference to FIG. 1. The remarks relating to the elements of FIG. 1 which also apply to the elements of FIG. 3 are not repeated subsequently. Only the differences are detailed in the following.

According to the example of FIG. 3, the radiocommunication station 10 includes a second measurement sensor. The second measurement sensor is a power measurement sensor 30 able to measure the power reflected by the filter 20.

In the case of FIG. 3, the control member 22 is able to control the impedance of a filter 20 according to two measurements. Both measurements are on the one hand the impedance of the antenna 12 and on the other hand the power reflected by the filter 20.

According to an embodiment, the control member 22 is able to control the impedance of the filter 20 so that the power reflected by the filter 20 is minimized.

For example, the control member 22 is able to control the impedance of the filter 20 so that the power reflected by the filter 20 is less than −15 dB.

According to the example of FIG. 3, the first capacitor 26 includes a first plurality of capacitors with a fixed capacitance each connected to a respective control switch. In the case of FIG. 3, the first capacitor 26 includes a capacitor 26A and a capacitor 26B. Each capacitor 26A and 26B is respectively associated with a switch 32A and 32B, the switch 32A being open while the switch 32B is closed.

Preferentially, each capacitor of the first plurality of capacitors includes a distinct fixed capacitance. The first plurality of capacitors thus forms a weight box.

Preferably, the number of capacitors with fixed capacitance is comprised between eight and sixteen. This means that on the one hand, the number of capacitors is greater than or equal to eight and, on the other hand that the number of capacitors is less than or equal to sixteen.

The control member 22 is able to control each switch.

As an example, the control member 22 includes a set of diodes, each diode giving the possibility of switching a switch. Each diode is thus associated with a respective component. More specifically, each diode is associated with a given capacitance.

According to an embodiment, each diode is powered by a DC voltage source.

According to an embodiment, each diode is a power diode from 500 V to 1,000 V which may operate up to powers of a few hundred watts.

Advantageously, each diode is a PIN diode.

A PIN (Positive Intrinsic Negative diode) diode is a diode consisting of a non-doped area, a so-called intrinsic area I, inserted between two doped areas P and N. A PIN diode biased in the direct direction (conducting) provides a dynamic impedance (with regards to variable signals) which is extremely low. Biased in the reverse direction (blocked) it provides a very large impedance and especially a very low capacitance (it behaves like a capacitor of very low value, of a few picofarads, or even much less depending on the versions).

Also, the second capacitor 28 includes a plurality of capacitors of fixed value each connected to a respective control switch. The control member 22 is able to control each switch. In the case of FIG. 3, the first capacitor 28 includes a capacitor 28A and a capacitor 28B. Each capacitor 28A and 28B is respectively associated with a switch 34A and 34B, each of the two switches 34A, 34B being closed.

The operation as well as the advantages of the radiocommunication station 10 according to FIG. 3 is similar to those described with reference to the exemplary radiocommunication station 10 described with reference to FIG. 1. They are therefore not further described here.

Each described embodiment may be combined with another embodiment described for giving another embodiment when this is technically possible.

Notably, according to an embodiment, electronic components other than capacitors comprise a first plurality of capacitors with fixed capacitance each connected to a respective controlled switch.

According to another embodiment, the filter 20 includes a plurality of LC circuit in series. For example, the filter 20 includes a plurality of LC circuits similar to FIG. 1 in series. In such a case, each output of an LC circuit is either connected to the input of the following LC circuit or to the antenna 12 (case of the last LC circuit when the filter 20 is covered from the input to the output).

Further, according to a preferred alternative, the member 22 for controlling the impedance of the filter 20 controls the impedance of the filter 20 so that the impedance of the antenna 12 is the optimum impedance of the amplifier 18. It should be noted that the optimum impedance of the amplifier 18 is in some cases, different from 50 ohms.

The impedance measurement sensor 14 gives the possibility of directly measuring the impedance of the antenna 13. Thus, the impedance matching of the filter 20 is based on a measured antenna impedance and not on a calculated impedance. The result of this is better matching of the antenna 13.

1. A radiocommunication station comprising:
an antenna having an impedance,
an impedance measurement sensor able to measure the impedance of the antenna in order to obtain a measured impedance,
an amplifier,
a filter connected to the antenna and to the amplifier, the filter having a variable impedance, and
a member for controlling the impedance of the filter, the member being able to control the impedance of the filter according to the measured impedance.

2. The station according to claim 1, wherein the filter comprises at least one electronic component of variable value.

3. The station according to claim 1, wherein said at least one electronic component of variable value comprises a plurality of electronic components of a fixed value each connected to a respective controlled switch, the control member being able to control each switch.

4. The station according to claim 1, wherein the control member is able to control the impedance of the filter so that the impedance of the filter is equal to the conjugate impedance of the impedance measured to within 10% of the modulus of the measured impedance.

5. The station according to claim 1, wherein the filter is an LC circuit.

6. The station according to claim 1, wherein the LC circuit includes an input and an output, an element generating an inductive impedance connecting the input to the output and a first capacitor connecting the input to the ground and a second capacitor connecting the output to the ground.

7. The station according to claim 1, wherein the station further includes:
a power measurement sensor, the power measurement sensor measuring the power reflected by the filter in order to obtain a measured reflected power,
the control member being able to control the impedance of the filter also according to the measured reflected power.

8. The station according to claim 1, wherein the control member is able to control the impedance of the filter at a regular time interval.

9. A device, notably a mobile phone, including a station according to claim 1.

10. An impedance matching method in a radiocommunication station comprising:
an antenna having an impedance,
an impedance measurement sensor,
an amplifier,
a filter connected to the antenna and to the amplifier, the filter having a variable impedance, and
a member for controlling the impedance of the filter,
the matching method including the steps of:
measuring the impedance of the antenna with the impedance measurement sensor in order to obtain a measured impedance, and
controlling the impedance of the filter according to the measured impedance.
